(19) United States
(12) Patent Application Publication
(10) Pub. No.: US 2017/0034901 A1
(43) Pub. Date: Feb. 2, 2017

(54) HEAT DISSIPATION STRUCTURE

(71) Applicants: Jia-Yu Hung, Taipei City (TW); Chang-Yuan Wu, Taipei City (TW); Ching-Ya Tu, Taipei City (TW); Tse-An Chu, Taipei City (TW)

(72) Inventors: Jia-Yu Hung, Taipei City (TW); Chang-Yuan Wu, Taipei City (TW); Ching-Ya Tu, Taipei City (TW); Tse-An Chu, Taipei City (TW)

(73) Assignee: COMPAL ELECTRONICS, INC., Taipei City (TW)

(21) Appl. No.: 15/293,303

(22) Filed: Oct. 14, 2016

Related U.S. Application Data
(63) Continuation of application No. 14/016,212, filed on Sep. 2, 2013.
(60) Provisional application No. 61/700,889, filed on Sep. 14, 2012.

(51) Int. Cl. H05K 1/02; H01L 23/367; H01L 23/373; G06F 1/20

(52) U.S. Cl. CPC H05K 1/0203; G06F 1/203; H01L 23/3675; H01L 23/3733

(57) ABSTRACT

A heat dissipation structure includes a first heat-conducting sheet, a second heat-conducting sheet and a meshed heat-conducting layer. The meshed heat-conducting layer is adhered between the first heat-conducting sheet and the second heat-conducting sheet. The meshed heat-conducting layer includes a plurality of first heat-conducting mediums and a plurality of second heat-conducting mediums, the first heat-conducting mediums and the second heat-conducting mediums are alternately arranged, and the thermal conductivity of each of the first heat-conducting mediums is less than the thermal conductivity of each of the second heat-conducting mediums.

### CROSS-REFERENCE TO RELATED APPLICATION

This application is a continuation application of and claims the priority benefit of a prior application Ser. No. 14/016,212, filed on Sep. 2, 2013, now pending. The prior application Ser. No. 14/016,212 claims the priority benefit of U.S. provisional application Ser. No. 61/700,889, filed on Sep. 14, 2012. The entirety of each of the above-mentioned patent applications is hereby incorporated by reference herein and made a part of this specification.

### BACKGROUND OF THE INVENTION

Field of the Invention

The invention generally relates to a heat dissipation structure, and more particularly, to a heat dissipation structure applicable to electronic devices.

Description of Related Art

In recent years, along with rapid progress of science and technology, the operation speed of an electronic device (such as a computer) gets increased continuously. Meanwhile, the heat produced by the heat-generating components inside an electronic device gets soaring steadily. In order to prevent over-heat of an electronic device to cause a temporary fault or permanent failure, cooling the heat-generating components inside an electronic device is a vital issue. In addition, the heat produced by the heat-generating components may be transmitted to the casing of the electronic device to make the over-heat of the casing. In this regard, the casings of some electronic devices need cooling as well.

The common heat dissipation methods currently are implemented by disposing heat-conducting sheets on the heat-generating components to bring away the heat produced by the heat-generating components or disposing the heat-conducting sheets at the inner surface of the casing of the electronic device to lower down the temperature of the casing. In general, the above-mentioned heat-conducting sheets are located between the heat-generating components and the casing. If the speed to transmit the heat produced by the heat-generating components in the heat-conducting sheets is too fast, the theimmial energy may be quickly transmitted to the casing before the heat is diffused to all portions of the heat-conducting sheets, which is unable to effectively avoid an over-high temperature of the casing to make the user uncomfortable.

### SUMMARY OF THE INVENTION

Accordingly, the invention is directed to a heat dissipation structure able to avoid a casing of an electronic device from over-high temperature.

The invention provides a heat dissipation structure suitable to reduce the temperature of a casing of an electronic device, which includes a first heat-conducting sheet, a second heat-conducting sheet and a meshed heat-conducting layer. The meshed heat-conducting layer is disposed between the first heat-conducting sheet and the second heat-conducting sheet. The meshed heat-conducting layer includes a plurality of first heat-conducting mediums and a plurality of second heat-conducting mediums, the first heat-conducting mediums and the second heat-conducting mediums are alternately arranged, and the thermal conductivity of each of the first heat-conducting mediums is less than the thermal conductivity of each of the second heat-conducting mediums.

In an embodiment of the invention, the meshed heat-conducting layer has a plurality of first holes, the first heat-conducting mediums are air in the first holes so as to form a plurality of air pillars in the meshed heat-conducting layer, and the second heat-conducting mediums form physical entity of the meshed heat-conducting layer excluding the first holes.

The invention provides a heat dissipation structure suitable to reduce the temperature of a casing of an electronic device, which includes a first heat-conducting sheet, a second heat-conducting sheet and a meshed heat-conducting layer. The meshed heat-conducting layer is adhered between the first heat-conducting sheet and the second heat-conducting sheet. The meshed heat-conducting layer has a plurality of first holes so as to form a plurality of first air pillars in the meshed heat-conducting layer.

In an embodiment of the invention, the shape of each of the first holes is cycle, ellipse, rectangle, trapezoid or triangle.

In an embodiment of the invention, the electronic device further has a heat-generating component, and the heat dissipation structure is disposed between the heat-generating component and the casing.

In an embodiment of the invention, the second heat-conducting sheet is located between the heat-generating component and the first heat-conducting sheet, and the thickness of the second heat-conducting sheet is greater than the thickness of the first heat-conducting sheet.

In an embodiment of the invention, the heat dissipation structure further includes a glue layer, in which the glue layer is adhered between the first heat-conducting sheet and the casing, the second heat-conducting sheet faces the heat-generating component and the glue layer further has a plurality of second holes so as to form a plurality of air pillars in the glue layer.

In an embodiment of the invention, the glue layer includes a plurality of third heat-conducting mediums and a plurality of fourth heat-conducting mediums, the third heat-conducting mediums and the fourth heat-conducting mediums are alternately arranged, and the thermal conductivity of each of the third heat-conducting mediums is less than the thermal conductivity of each of the fourth heat-conducting mediums.

In an embodiment of the invention, the glue layer further has a plurality of second holes, the third heat-conducting mediums are air in the second holes so as to form a plurality of air pillars in the glue layer, and the fourth heat-conducting mediums form physical entity of the glue layer excluding the second holes.

In an embodiment of the invention, when the casing is a metallic material or there is a conductive layer at the contact position between the casing and the glue layer, the glue layer is a conductive glue.

In an embodiment of the invention, the heat dissipation structure further includes a thermal glue, in which the thermal glue is adhered between the second heat-conducting sheet and the heat-generating component, the first heat-conducting sheet faces the casing and the first heat-conducting sheet and the casing are separated by an interval.

In an embodiment of the invention, the heat dissipation structure further includes an insulation layer, in which the heat-generating component is disposed on a circuit board, a surface of the second heat-conducting sheet faces the circuit board and the insulation layer is disposed on the surface of the second heat-conducting sheet.

In an embodiment of the invention, the materials of the first heat-conducting sheet and the second heat-conducting sheet are metal or ceramic and the first heat-conducting sheet and the second heat-conducting sheet are parallel to each other.

In an embodiment of the invention, the meshed heat-conducting layer is a glue layer.

In an embodiment of the invention, the glue layer is a patch-type glue layer.

Based on the depiction above, the meshed heat-conducting layer between the first heat-conducting sheet and the second heat-conducting sheet in the invention includes multiple first heat-conducting mediums and multiple second heat-conducting mediums, in which the thermal conductivity of each of the first heat-conducting mediums (for example, the air in a plurality of openings of the meshed heat-conducting layer) is less than the thermal conductivity of each of the second heat-conducting mediums (for example, the physical entity of the meshed heat-conducting layer excluding the openings). Since the meshed heat-conducting layer has the first heat-conducting mediums therein with a lower thermal conductivity, the speed for the thermal energy to be transmitted to the first heat-conducting sheet from the second heat-conducting sheet via the meshed heat-conducting layer can be reduced, which can avoid the thermal energy from being quickly transmitted to the first heat-conducting sheet before the heat is not evenly diffused to all portions of the second heat-conducting sheets so as to ensure the casing of the electronic device adjacent to the first heat-conducting sheet without over-heat to make the user uncomfortable.

In order to make the features and advantages of the present invention more comprehensible, the present invention is further described in detail in the following with reference to the embodiments and the accompanying drawings.

### BRIEF DESCRIPTION OF THE DRAWINGS

FIG. 1 is a cross-sectional diagram of a heat dissipation structure applied in an electronic device according to an embodiment of the invention.

FIG. 2 is a top-view diagram of the meshed heat-conducting layer in FIG. 1.

FIG. 3 is a top-view diagram of the glue layer in FIG. 1.

FIG. 4 is a top-view diagram of a meshed heat-conducting layer according to another embodiment of the invention.

FIG. 5 is a top-view diagram of a glue layer according to another embodiment of the invention.

FIG. 6 is a cross-sectional diagram of a heat dissipation structure applied in an electronic device according to another embodiment of the invention.

FIG. 7 is a top-view diagram of the meshed heat-conducting layer in FIG. 6.

### DESCRIPTION OF THE EMBODIMENTS

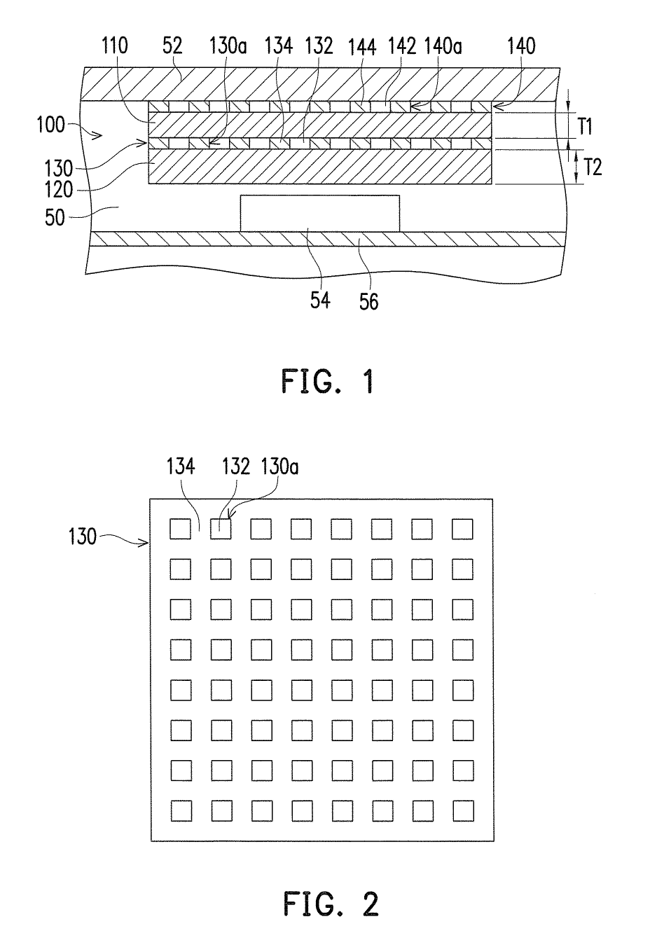

FIG. 1 is a cross-sectional diagram of a heat dissipation structure applied in an electronic device according to an embodiment of the invention and FIG. 2 is a top-view diagram of the meshed heat-conducting layer in FIG. 1. Referring to FIGS. 1 and 2, a heat dissipation structure 100 of the embodiment is suitable to be used in an electronic device 50, in which the electronic device 50 is, for example, a notebook computer or other types of electronic devices and includes a casing 52 and a heat-generating component 54. The heat-generating component 54 is, for example, a central processing unit (CPU) or other types of electronic devices. The heat-generating component 54 is disposed on a circuit board 56 of the electronic device 50. The heat dissipation structure 100 is disposed between the heat-generating component 54 and the casing 52.

The heat dissipation structure 100 includes a first heat-conducting sheet 110, a second heat-conducting sheet 120 and a meshed heat-conducting layer 130. The materials of the first heat-conducting sheet 110 and the second heat-conducting sheet 120 are, for example, metal, ceramic or other appropriate heat-conducting materials, which the invention is not limited to. The first heat-conducting sheet 110 and the second heat-conducting sheet 120 are parallel to each other. The meshed heat-conducting layer 130 is, for example, a glue layer. The meshed heat-conducting layer 130 is adhered between the first heat-conducting sheet 110 and the second heat-conducting sheet 120 and includes a plurality of first heat-conducting mediums 132 and a plurality of second heat-conducting mediums 134. The first heat-conducting sheet 110 faces the casing 52, the second heat-conducting sheet 120 faces the heat-generating component 54, and the second heat-conducting sheet 120 and the heat-generating component 54 are separated by an interval. The first heat-conducting mediums 132 and the second heat-conducting mediums 134 are alternately arranged, and the thermal conductivity of each of the first heat-conducting mediums 132 is less than the thermal conductivity of each of the second heat-conducting mediums 134. In more details, the meshed heat-conducting layer 130 of the embodiment has a plurality of first holes 130a, the first heat-conducting mediums 132 are air filling into the first holes 130a to form a plurality of air pillars in the meshed heat-conducting layer 130, while the second heat-conducting mediums 134 form physical entity of the meshed heat-conducting layer 130 excluding the first holes 130a.

Under the above-mentioned layout, since the meshed heat-conducting layer 130 has multiple first heat-conducting mediums 132 therein with a lower thermal conductivity, so that it can reduce the speed for the thermal energy to be transmitted to the first heat-conducting sheet 110 from the second heat-conducting sheet 120 via the meshed heat-conducting layer 130 and thus can avoid the thermal energy from being quickly transmitted to the first heat-conducting sheet 110 before being evenly diffused to all the portions of the second heat-conducting sheet 120, which can ensure the casing 52 of the electronic device 50 adjacent to the first heat-conducting sheet 110 from over-heat to cause the user uncomfortable.

As shown in FIG. 2, the shape of each of the first holes 130a of the meshed heat-conducting layer 130 in the embodiment is rectangle, which the invention is not limited to. In other embodiments, each of the first holes 130a can be cycle, ellipse, rectangle, trapezoid, triangle or other shapes.

Referring to FIG. 1, the second heat-conducting sheet 120 in the embodiment is located between the heat-generating component 54 and the first heat-conducting sheet 110, and the thickness T2 of the second heat-conducting sheet 120 is greater than the thickness T1 of the first heat-conducting sheet 110. Since the second heat-conducting sheet 120 has a larger thickness T2, when the thermal energy produced by the heat-generating component 54 is transmitted to the second heat-conducting sheet 120, the thermal energy can be fully diffused in the second heat-conducting sheet 120, followed by being transmitted to the first heat-conducting sheet 110 so as to further moderate the speed for the thermal energy to be transmitted to the casing 52 of the electronic device 50.

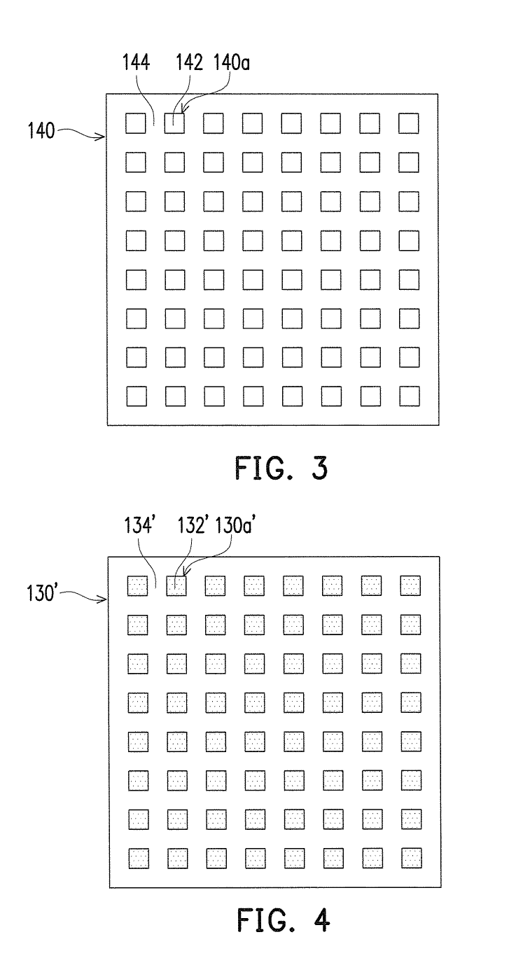

FIG. 3 is a top-view diagram of the glue layer in FIG. 1. Referring to FIGS. 1 and 3, the heat dissipation structure 100 in the embodiment further includes a glue layer 140, which is, for example, a patch-type glue layer. The glue layer 140 is adhered between the first heat-conducting sheet 110 and the casing 52 and includes a plurality of third heat-conducting mediums 142 and a plurality of fourth heat-conducting mediums 144. The third heat-conducting mediums 142 and the fourth heat-conducting mediums 144 are alternately arranged, and the thermal conductivity of each of the third heat-conducting mediums 142 is less than the thermal conductivity of each of the fourth heat-conducting mediums 144. In more details, the glue layer 140 in the embodiment has a plurality of second holes 140a, the third heat-conducting mediums 142 are air filling into the second holes 140a so as to form a plurality of air pillars in the glue layer 140, while the fourth heat-conducting mediums 144 form the physical entity of the glue layer 140 excluding the second holes 140a. Similarly to the above-mentioned mechanism of the meshed heat-conducting layer 130, since the glue layer 140 has multiple third heat-conducting mediums 142 therein with a lower thermal conductivity, so that it can reduce the speed for the thermal energy to be transmitted to the casing 52 from the first heat-conducting sheet 110 via the glue layer 140 and thus can avoid the thermal energy from being quickly transmitted to the casing 52 before being evenly diffused to all the portions of the first heat-conducting sheet 110, which can ensure the casing 62 from over-heat to cause the user uncomfortable. Depending on the different products, when the casing of the electronic device is a metallic material or has a casing made of a conductive layer with grounding function, the glue layer is a conductive glue and the fourth heat-conducting mediums are conductive so as to avoid a noise interference point is formed at the contact position between the glue layer and the casing to affect the antenna signal when the nonconductive glue layer is conducting the casing with grounding function.

As shown in FIG. 3, the shape of each of the second holes 140a of the glue layer 140 in the embodiment is rectangle, which the invention is not limited to. In other embodiments, the shape of each of the second holes 140a can be cycle, ellipse; rectangle, trapezoid, triangle or other shapes.

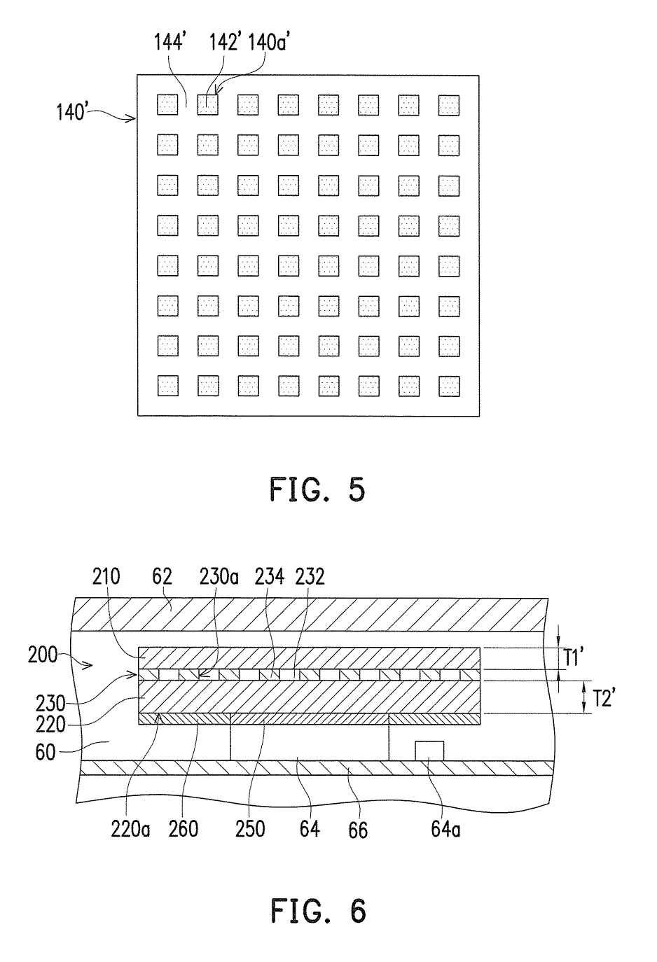

In the above-mentioned embodiment, both the first heat-conducting mediums 132 and the third heat-conducting mediums 142 are air, which the invention is not limited to. In following, some examples accompanying with figures are explained. FIG. 4 is a top-view diagram of a meshed heat-conducting layer according to another embodiment of the invention and FIG. 5 is a top-view diagram of a glue layer according to another embodiment of the invention. In a meshed heat-conducting layer 130′ of FIG. 4, the first heat-conducting mediums 132′ in each of the first holes 130a′ are not air, but physical material with a lower thermal conductivity (lower than the thermal conductivity of the second heat-conducting mediums 134′). Similarly, in the glue layer 140′ of FIG. 5, the third heat-conducting mediums 142′ in each of the second holes 140a′ are not air, but physical material with a lower thermal conductivity (lower than the thermal conductivity of the fourth heat-conducting mediums 144′).

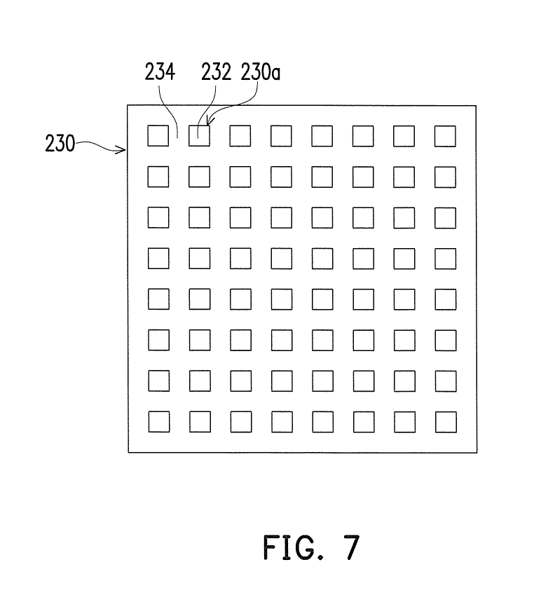

FIG. 6 is a cross-sectional diagram of a heat dissipation structure applied in an electronic device according to another embodiment of the invention and FIG. 7 is a top-view diagram of the meshed heat-conducting layer in FIG. 6. Referring to FIGS. 6 and 7, a heat dissipation structure 200 in the embodiment is suitable for an electronic device 60, and the electronic device 60 is, for example, a notebook computer or other types of electronic devices and includes a casing 62 and a heat-generating component 64. The heat-generating component 64 is, for example, a central processing unit (CPU) or other types of electronic devices. The heat-generating component 64 is disposed on a circuit board 66 of the electronic device 60. The heat dissipation structure 200 is disposed between the heat-generating component 64 and the casing 62.

The heat dissipation structure 200 includes a first heat-conducting sheet 210, a second heat-conducting sheet 220 and a meshed heat-conducting layer 230. The materials of the first heat-conducting sheet 210 and the second heat-conducting sheet 220 are, for example, metal, ceramic or other appropriate heat-conducting materials, which the invention is not limited to. The first heat-conducting sheet 210 and the second heat-conducting sheet 220 are parallel to each other. The meshed heat-conducting layer 230 is adhered between the first heat-conducting sheet 210 and the second heat-conducting sheet 220 and includes a plurality of first heat-conducting mediums 232 and a plurality of second heat-conducting mediums 234. The first heat-conducting sheet 210 faces the casing 62, the second heat-conducting sheet 220 faces the heat-generating component 64, and the first heat-conducting sheet 210 and the casing 62 are separated by an interval. The first heat-conducting mediums 232 and the second heat-conducting mediums 234 are alternately arranged, and the thermal conductivity of each of the first heat-conducting mediums 232 is less than the thermal conductivity of each of the second heat-conducting mediums 234. In more details, the meshed heat-conducting layer 230 of the embodiment has a plurality of first holes 230a, the first heat-conducting mediums 232 are air filling into the first holes 230a, while the second heat-conducting mediums 234 form physical entity of the meshed heat-conducting layer 230 excluding the first holes 230a.

Under the above-mentioned layout, since the meshed heat-conducting layer 230 has multiple first heat-conducting mediums 232 therein with a lower thermal conductivity, so that it can reduce the speed for the thermal energy to be transmitted to the first heat-conducting sheet 210 from the second heat-conducting sheet 220 via the meshed heat-conducting layer 230 and thus can avoid the thermal energy from being quickly transmitted to the first heat-conducting sheet 210 before being evenly diffused to all the portions of the second heat-conducting sheet 220, which can ensure the casing 62 of the electronic device 60 adjacent to the first heat-conducting sheet 210 from over-heat to cause the user uncomfortable.

As shown in FIG. 7, the shape of each of the first holes 230a of the meshed heat-conducting layer 230 in the embodiment is rectangle, which the invention is not limited to. In other embodiments, each of the first holes 230a can be cycle, ellipse, rectangle, trapezoid, triangle or other shapes.

Referring to FIG. 6, the second heat-conducting sheet 220 in the embodiment is located between the heat-generating component 64 and the first heat-conducting sheet 210, and the thickness T2′ of the second heat-conducting sheet 220 is greater than the thickness T1′ of the first heat-conducting sheet 210. Since the second heat-conducting sheet 220 has a larger thickness T2′, when the thermal energy produced by the heat-generating component 64 is transmitted to the second heat-conducting sheet 220, the thermal energy can be fully diffused in the second heat-conducting sheet 220, followed by being transmitted to the first heat-conducting sheet 210 so as to further moderate the speed for the thermal energy to be transmitted to the casing 62 of the electronic device 60.

In the above-mentioned embodiment, the first heat-conducting mediums 232 is air, which the invention is not limited to. In other embodiments, the first heat-conducting mediums 232 in each of the first holes 230a is not air, but physical material with a lower thermal conductivity.

Referring to FIG. 6, the heat dissipation structure 200 of the embodiment further includes a thermal glue 250. The thermal glue 250 is adhered between the second heat-conducting sheet 220 and the heat-generating component 64 so as to make the thermal energy produced by the heat-generating component 64 quickly transmitted to the second heat-conducting sheet 220 via the thermal glue 250. In addition, the heat dissipation structure 200 further includes an insulation layer 260, the surface 220a of the second heat-conducting sheet 220 faces the circuit board 64 and the insulation layer 260 is disposed at the surface 220a of the second heat-conducting sheet 220 to avoid the electronic device 60a on the circuit board 64 from being unexpected conductible to the second heat-conducting sheet 220.

In summary, the meshed heat-conducting layer between the first heat-conducting sheet and the second heat-conducting sheet in the invention includes multiple first heat-conducting mediums and multiple second heat-conducting mediums, in which the thermal conductivity of each of the first heat-conducting mediums (for example, the air in a plurality of openings of the meshed heat-conducting layer) is less than the thermal conductivity of each of the second heat-conducting mediums (for example, the physical entity of the meshed heat-conducting layer excluding the openings). Since the meshed heat-conducting layer has the first heat-conducting mediums therein with a lower thermal conductivity, the speed for the thermal energy to be transmitted to the first heat-conducting sheet from the second heat-conducting sheet via the meshed heat-conducting layer can be reduced, which can avoid the thermal energy from being quickly transmitted to the first heat-conducting sheet before the heat is not evenly diffused to all portions of the second heat-conducting sheets so as to ensure the casing of the electronic device adjacent to the first heat-conducting sheet without over-heat to make the user uncomfortable. In addition, by means of the design that the second heat-conducting sheet adjacent to the heat-generating component has a larger thickness, the thermal energy come from the heat-generating component is transmitted to the first heat-conducting sheet only after being fully diffused in the second heat-conducting sheet so as to further moderate the speed for the thermal energy to be transmitted to the casing of the electronic device.

It will be apparent to those skilled in the art that the descriptions above are several preferred embodiments of the invention only, which does not limit the implementing range of the invention. Various modifications and variations can be made to the structure of the invention without departing from the scope or spirit of the invention. The claim scope of the invention is defined by the claims hereinafter.

What is claimed is:

1. A heat dissipation structure suitable to reduce the temperature of a casing of an electronic device having a heat-generating component, comprising:
a first heat-conducting sheet;
a second heat-conducting sheet;
a meshed heat-conducting layer, disposed between the first heat-conducting sheet and the second heat-conducting sheet, wherein the meshed heat-conducting layer comprises a plurality of first heat-conducting mediums and a plurality of second heat-conducting mediums, the first heat-conducting mediums and the second heat-conducting mediums are alternately arranged, and the thermal conductivity of each of the first heat-conducting mediums is less than the thermal conductivity of each of the second heat-conducting mediums; and
a thermal glue, wherein the thermal glue is adhered between the second heat-conducting sheet and the heat-generating component, the first heat-conducting sheet faces the casing and the first heat-conducting sheet and the casing are separated by an interval.

2. The heat dissipation structure as claimed in claim 1, wherein the meshed heat-conducting layer has a plurality of first holes, the first heat-conducting mediums are air in the first holes so as to form a plurality of air pillars in the meshed heat-conducting layer, and the second heat-conducting mediums form a physical entity of the meshed heat-conducting layer excluding the first holes.

3. The heat dissipation structure as claimed in claim 2, wherein the shape of each of the first holes is a circle, ellipse, rectangle, trapezoid or triangle.

4. The heat dissipation structure as claimed in claim 1, wherein the heat dissipation structure is disposed between the heat-generating component and the casing.

5. The heat dissipation structure as claimed in claim 4, wherein the second heat-conducting sheet is located between the heat-generating component and the first heat-conducting sheet, and the thickness of the second heat-conducting sheet is greater than the thickness of the first heat-conducting sheet.

6. The heat dissipation structure as claimed in claim 4, further comprising an insulation layer, wherein the heat-generating component is disposed on a circuit board, a surface of the second heat-conducting sheet faces the circuit board and the insulation layer is disposed on the surface of the second heat-conducting sheet.

7. The heat dissipation structure as claimed in claim 1, wherein the materials of the first heat-conducting sheet and the second heat-conducting sheet are metal or ceramic and the first heat-conducting sheet and the second heat-conducting sheet are parallel to each other.

8. The heat dissipation structure as claimed in claim 1, wherein the meshed heat-conducting layer is a glue layer.

9. A heat dissipation structure suitable to reduce the temperature of a casing of an electronic device having a heat-generating component, comprising:
a first heat-conducting sheet;
a second heat-conducting sheet;
a meshed heat-conducting layer, adhered between the first heat-conducting sheet and the second heat-conducting sheet, wherein the meshed heat-conducting layer has a plurality of first holes to form a plurality of first air pillars in the meshed heat-conducting layer; and
a thermal glue, wherein the thermal glue is adhered between the second heat-conducting sheet and the heat-generating component, the first heat-conducting sheet faces the casing and the first heat-conducting sheet and the casing are separated by an interval.

10. The heat dissipation structure as claimed in claim 9, wherein the shape of each of the first holes is a circle, ellipse, rectangle, trapezoid or triangle.

11. The heat dissipation structure as claimed in claim 9, wherein the heat dissipation structure is disposed between the heat-generating component and the casing.

12. The heat dissipation structure as claimed in claim 11, wherein the second heat-conducting sheet is located between the heat-generating component and the first heat-conducting sheet, and the thickness of the second heat-conducting sheet is greater than the thickness of the first heat-conducting sheet.
